(19) United States
(12) Patent Application Publication
(10) Pub. No.: US 2002/0172028 A1
(43) Pub. Date: Nov. 21, 2002

(54) Connector carrier and method for connecting the connector carrier to an injection molded part

(76) Inventors: Mathias Linssen, Litzendorf (DE); Christof Vogel, Bischberg (DE)

Correspondence Address: KENYON & KENYON, ONE BROADWAY, NEW YORK, NY, 10004, US

(21) Appl. No.: 10/070,142

(22) PCT Filed: Jul. 4, 2001
(86) PCT No.: PCT/DE01/02412

(30) Foreign Application Priority Data
Jul. 4, 2000 (DE) 100 32 337.5

(51) Int. Cl. B29C 45/14; H05K 7/02

(52) U.S. Cl. 361/809; 264/250; 361/826

(57) ABSTRACT

A connection carrier, e.g., a connection carrier for the bobbins of solenoids, includes a positioning section for positioning the connection carrier in a recess of an injection-molded part surrounding the connection carrier and includes a locking section projecting over the width of the positioning section for anchoring the connection carrier in the injection-molded part.

### BACKGROUND INFORMATION

The present invention relates to a connection carrier according to the definition of the species in claim 1 and a method for joining the connection carrier to an injection-molded part according to the definition of the species in claim 11.

A connection carrier according to the definition of the species is known, for example, from German Patent Application 43 32 172 A1 and, especially for solenoids, from German Patent 295 14 315 U1.

The embedding of metallic connection carriers into an injection-molded part, in particular into the bobbin of a solenoid, which is used, for example, in (high-pressure) fuel injectors, usually takes place during production of the injection-molded part. In doing this, the connection carrier is positioned at the correct location in the injection mold, and the injection-molded part is then produced in the mold. This embeds the connection carrier into the injection-molded part.

The disadvantage of the method described above lies, in particular, in its high production costs, since the necessary tools must be sealed against the injection pressure, thus increasing the tool costs.

In addition, it is not possible to position the connection carrier in the injection-molded part with a sufficient degree of accuracy, and the connection carrier can additionally shift position or rotate during later processing steps if the plastic has not yet been fully cured.

Due to the shape of commonly used connection carriers, it is also not possible to prevent the connection carrier from slipping out of the injection-molded part after curing, since no locking elements are provided to hold the connection carrier in place under tensile load.

### ADVANTAGES OF THE INVENTION

The connection carrier according to the present invention, having the features of claim 1, and the method according to the present invention for joining the connection carrier to an injection-molded part, having the features of claim 11, have the advantage over the related art that the connection carrier is joined to the injection-molded part so that it is precisely and immovably anchored in a defined location.

The connection carrier may be injected into the finished injection-molded part without a great deal of engineering effort, while achieving high positioning accuracy, since the plastic has already been largely cured, and the position of the injected connection carrier is therefore no longer variable.

The features described in the subordinate claims indicate advantageous embodiments of the connection carrier described in claim 1 and the method described in claim 11.

One particular advantage is the simple shape of the connection carrier, which may be punched out of a metal sheet in the conventional manner, along with the anchoring elements.

The design of the anchoring elements is freely selectable, including a saw-tooth shape as well as, for example, an angular or rounded shape.

Another advantage is that the area of the injection-molded part where the connection carrier is injected may be preformed by slightly modifying existing injection molds.

### DRAWING

One embodiment of the present invention is illustrated in simplified form in the drawing and explained in greater detail in the following description, where

FIG. 1 shows a schematic longitudinal section of a connection carrier according to the present invention and the correspondingly shaped injection area of an injection-molded part; and

FIG. 2 shows a schematic view of a bobbin for a solenoid, having two connection carriers designed according to the present invention.

### DESCRIPTION OF THE EMBODIMENT

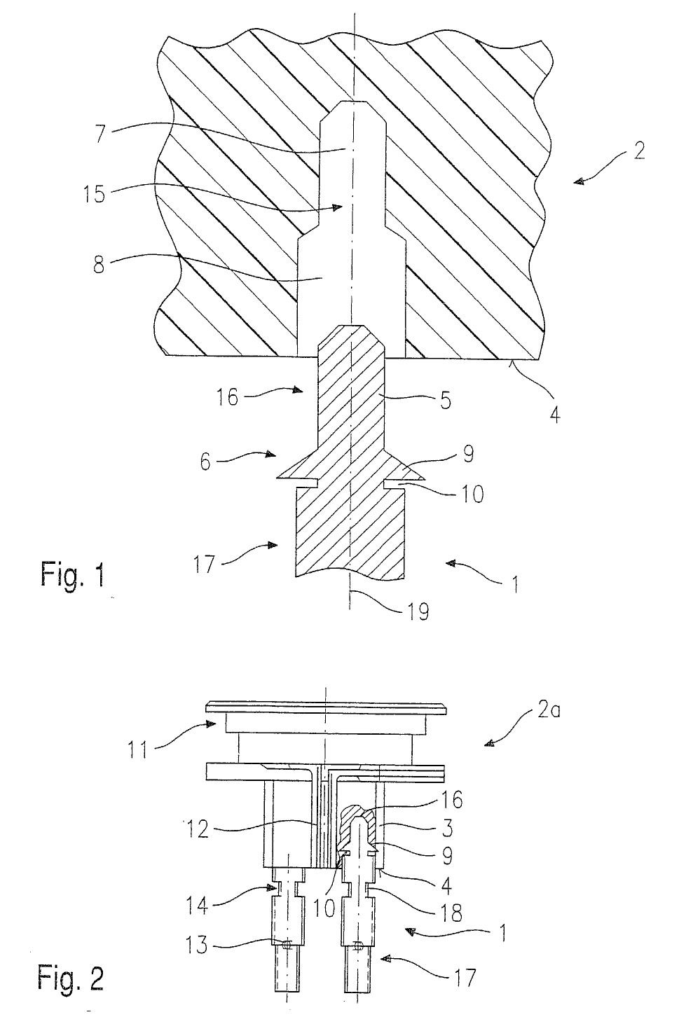

FIG. 1 shows an extract of a schematic sectional representation of a first embodiment of a connection carrier 1 according to the present invention. Connection carrier 1 is used, in particular, in fuel injectors, where it establishes the connection between a solenoid wound onto a bobbin and an electronic control unit for operating the fuel injector. The bobbin is produced by injection molding.

Connection carrier 1 preferably has a flat shape and is produced by punching it from a metal sheet. It may have fastening holes 13 and recesses 18 in a bending area 14 (FIG. 2) that enable connection carrier 1 to be further processed after it has been inserted into an injection-molded part 2, such as a bobbin.

In the present embodiment, connection carrier 1 has a tab-shaped positioning section 5, which forms a first end 16 of connection carrier 1. Positioning section 5 may be designed with a round or polygonal shape. Positioning section 5 of connection carrier 1 ensures the precise positioning of connection carrier 1 in injection-molded part 2.

Positioning section 5 of connection carrier 1 is followed by a locking section 6. The latter helps securely anchor connection carrier 1 in injection-molded part 2. In the present embodiment, locking section 6 of connection carrier 1 is designed in the form of two projections 9, which have a saw-toothed shape. Projections 9 are offset against a second end 17 of connection carrier 1 by recesses 10. The purpose of recesses 10 is to absorb any forming energy that occurs while connection carrier 1 is being inserted into injection-molded part 2, thus preventing connection carrier 1 from bending in bending area 14. As shown in FIG. 2, second end 17 of connection carrier 1 may have fastening holes 13 and recesses 18 in bending area 14 for fasting the wire ends of the solenoid and to facilitate further processing.

Injection-molded part 2 has a corresponding recess 15 into which connection carrier 1 is inserted. Recess 15 is divided into a positioning area 7 and a locking area 8. Positioning area 7 is shaped so that positioning section 5 of connection carrier 1 fits snugly when inserted. Locking area 8 of recess 15 has a width perpendicular to a longitudinal axis 19 of connection carrier 1 that is equal to the width of second end 17 of connection carrier 1. However, projections 9 of connection carrier 1, which anchor connection carrier 1 in injection-molded part 2, are larger in width. As a result, connection carrier 1 is securely anchored in injection-molded part 2, since projections 9 dig into the plastic of injection-molded part 2. Inserting connection carrier 1 into injection-molded part 2 also causes a slight deformation of projections 9, bending them like hooks away from the direction of insertion after connection carrier 1 has been inserted into injection-molded part 2.

Connection carrier 1 is inserted into injection-molded part 2 by injecting it shortly before the plastic of injection-molded part 2 has completely cured. Injection can take place, for example, using compressed air. Connection carrier 1 is anchored in injection-molded part 2 by barb-like projections 9 so that it is no longer possible to withdraw connection carrier 1 from recess 15 in injection-molded part 2 even after the plastic of injection-molded part 2 has completely cured. The deformation of projections 9 produced during injection causes them to spread further.

Briefly heating the plastic of injection-molded part 2 once again during additional processing steps, for example when soldering the wire ends of the solenoid to connection carrier 1, increases the form fit between injection-molded part 2 and connection carrier 1 in locking area 8 without affecting the position of connection carrier 1 in injection-molded part 2.

This effect may be further enhanced by increasing the mounting length and/or increasing the injection depth of connection carrier 1 in injection-molded part 2, since the positioning and locking functions may be spaced far apart from each other.

FIG. 2 shows a schematic representation of an embodiment of connection carrier 1 according to the present invention. Injection-molded part 2 in this case is designed as a bobbin 2a which holds windings (not illustrated in further detail) of a solenoid for operating a fuel injector (not illustrated in further detail).

Bobbin 2a has a winding area 11 that accepts the solenoid windings in a further processing step. The ends of the winding are routed to connection carrier 1 through wire guides 12 over an extension 3 of bobbin 2a.

Connection carriers 1 are provided at one end 4 of extension 3. Connection carriers 1 have fastening holes 13 for the solenoid wire ends as well as a bending area 14 in which connection carriers 1 may be bent during additional processing steps. As demonstrated for right connection carrier 1 in FIG. 2, first end 16 of connection carriers 1 may have the design illustrated in greater detail in FIG. 1 and may be inserted into bobbin 2a according to the method described above for joining connection carrier 1 to injection-molded part 2.

The present invention is not limited to the illustrated embodiment, but is also suitable for connection carriers 1 having a great many other shapes. The method according to the present invention may be used for inserting any metal parts into a preformed injection-molded part.

What is claimed is:

1. A connection carrier (1), in particular a connection carrier (1) for the bobbins of solenoids,
wherein the connection carrier (1) has a positioning section (5) for positioning the connection carrier (1) in a recess (15) of an injection-molded part (2) surrounding the connection carrier (1); and a locking section (6) projecting over the width of the positioning section (5) for anchoring the connection carrier (1) in the injection-molded part (2).

2. The connection carrier according to claim 1,
wherein the positioning section (5) of the connection carrier (1) forms a first end (16) of the connection carrier (1).

3. The connection carrier according to claim 1 or 2,
wherein the positioning section (5) of the connection carrier (1) is designed in the shape of a tab.

4. The connection carrier according to claim 2 or 3,
wherein the first end (16) of the connection carrier (1) forming the positioning section (5) of the connection carrier (1) is designed with a round shape.

5. The connection carrier according to claim 2 or 3,
wherein the first end (16) of the connection carrier (1) forming the positioning section (5) of the connection carrier (1) is designed with a polygonal shape.

6. The connection carrier according to one of claims 1 through 5,
wherein the locking section (6) of the connection carrier (1) has at least two projections (9).

7. The connection carrier according to claim 6,
wherein the projections (9) are designed with a saw-toothed shape.

8. The connection carrier according to claim 6 or 7,
wherein the projections (9) are offset by recesses (10) against a second end (17) of the connection carrier (1).

9. The connection carrier according to claim 8,
wherein the recess (15) in the injection-molded part (2) has a positioning area (7) and a locking area (8); and the positioning section (5) of the connection carrier (1) is designed so that the positioning section (5) fits snugly when inserted into the positioning area (7) of the injection-molded part (2).

10. The connection carrier according to claim 9,
wherein the width of the locking area (8) in the injection-molded part (2) is smaller in extension than the locking section (6) of the connection carrier (1) in the area of the projections (9).

11. A method for joining a connection carrier (1), in particular a connection carrier (1) for the bobbins of solenoids, to an injection-molded part (2), with the connection carrier (1) having a positioning section (5) for positioning the connection carrier (1) in a recess (15) of an injection-molded part (2) surrounding the connection carrier (1); and a locking section (6) projecting over the width of the positioning section (5) for anchoring the connection carrier (1) in the injection-molded part (2); comprising the following steps:
punching out the connection carrier (1);
preforming the injection-molded part (2) to fit the shape of the connection carrier (1);
injecting the connection carrier (1) into the injection-molded part (2).

12. The method according to claim 11,
wherein the injection-molded part (2) has a positioning area (7) and a locking area (8); and the connection carrier (1) is injected so that the positioning section (5) of the connection carrier (1) fits snugly when inserted into the positioning area (7) of the injection-molded part (2), and the locking section (6) of the connection carrier (1) projecting over the width of the positioning section (5) is locked in place in the locking area (8) of the injection-molded part (2).
